(19) United States
(12) Patent Application Publication
(10) Pub. No.: US 2024/0258173 A1
(43) Pub. Date: Aug. 1, 2024

(54) SEMICONDUCTOR DEVICE

(71) Applicant: MITSUBOSHI DIAMOND INDUSTRIAL CO., LTD., Settsu city (JP)

(72) Inventors: Mitsuru KITAICHI, Settsu city (JP); Yoshiyuki ASAI, Settsu city (JP); Masakazu TAKEDA, Settsu city (JP)

(21) Appl. No.: 18/627,863

(22) Filed: Apr. 5, 2024

Related U.S. Application Data
(63) Continuation of application No. PCT/JP2022/036050, filed on Sep. 28, 2022.

(30) Foreign Application Priority Data
Oct. 8, 2021 (JP) 2021-166200

(51) Int. Cl. H01L 21/82; H01L 23/544; H01L 29/16

(52) U.S. Cl. CPC H01L 21/8213; H01L 23/544; H01L 29/1608; H01L 2223/5446

(57) ABSTRACT

A semiconductor device includes a semiconductor layer (2) composed of a single crystal. The semiconductor device comprises a mounted surface on which an element is mounted, a non-mounted surface opposed to the mounted surface, and a compressive stress field in an outer peripheral region on at least one of the mounted surface and the non-mounted surface.

### CROSS REFERENCE TO RELATED APPLICATIONS

This application is a continuation application of International Application No. PCT/JP2022/036050, filed on Sep. 28, 2022, which claims the benefit of priority to Japanese Patent Application No. 2021-166200, filed on Oct. 8, 2021. The entire contents of each of these applications are hereby incorporated herein by reference.

### BACKGROUND OF THE INVENTION

### 1. Field of the Invention

The present invention relates to a semiconductor device.

### 2. Description of the Related Art

Generally, a manufacturing process of a semiconductor device includes a step of producing a semiconductor wafer, a step of forming a plurality of semiconductor elements (electronic circuits) on the semiconductor wafer, a step of dividing the semiconductor wafer on which the semiconductor elements have been formed and thereby individualizing a plurality of semiconductor chips (semiconductor devices), and a step of assembling a plurality of the semiconductor devices by using the semiconductor chips.

One method for cutting out a semiconductor chip from a semiconductor wafer is blade dicing. Another method for individualizing the plurality of semiconductor chips is disclosed in International Application Publication No. WO 2019/082724 A1 (referred to as Patent Document 1), and a technique concerning a structure of the semiconductor chip is disclosed in Japanese Unexamined Patent Application Publication No. 2018-157168 (referred to as Patent Document 2).

Patent Document 1 discloses scribing a metal-film coated substrate (a semiconductor wafer) having a metal film thereon and breaking (dividing) the substrate a scribing line by means of a breaking bar. Specifically, a plurality of scribing lines are formed on a first main surface having a metal film coated thereon, from each of which a plurality of vertical cracks extend into the substrate, and a breaking bar is contacted onto a second main surface having no metal film coated thereon to further extend the vertical crack, thereby to divide the metal-film coated substrate.

Patent Document 2 discloses a semiconductor device (semiconductor chip) improving adhesion between the semiconductor device (semiconductor chip) and a sealing material and enhancing strength of the semiconductor device. The semiconductor device has bending portions along at least two modified zones formed on a side of a substrate by laser irradiation. The two bending portions are shifted from each other in a direction perpendicular to the substrate surface and a direction parallel to the substrate surface, so as define two rough surfaces (modified zones) close to the bending portions and three smooth surfaces (one between a substrate top surface and one of the modified zones, one between two of the modified zones, and one between the other one of the modified zones and a substrate bottom surface). The modified zones have residual stress greater than both of the substrate top surface and the substrate bottom surface irrespective of whether the residual stress is compressive stress or tensile stress.

When a semiconductor device (semiconductor chip) is manufactured by dividing a semiconductor wafer made of a crystalline brittle material such as SiC by blade dicing, chipping and microcracks occur on a cutting end surface since the division involves material removal. Furthermore, sizes of the chipping and microcracks are substantial as several tens of micrometers.

In recent years, as the degree of integration and performance of the semiconductor chips has been enhanced, an amount of heat generated during operation of the semiconductor chips tends to increase. The increased heat results in generation of unexpected thermal stress (tensile stress) in a semiconductor device, which causes breakage (e.g., thermal stress cracking) of the semiconductor device (see FIG. 1(a)). In a case where the semiconductor device generates heat, the tensile stress acts on an outer peripheral region of the semiconductor device, which causes a fracture to extend from a relatively large chipping or microcrack formed by blade dicing. This affects device functions or breaks the semiconductor device itself.

Although several countermeasures have been suggested to suppress a rise in temperature of the semiconductor device by using a heatsink or the like, it is predicted that further integration and performance of the semiconductor devices will be enhanced in the future, and therefore there is an urgent need for development of a semiconductor chip (semiconductor device) which withstands thermal stress to prevents from being cracked on the edge thereof.

The inventors of the present invention have found through diligent studies, that the fracture extending from the chipping or the microcrack can be suppressed by reducing the chipping and the microcracking in number and size on sides of the semiconductor device and additionally by forming a compressive stress field adjacent to outer peripheral region (edge members) on top or bottom main surface of the semiconductor device, and developed a technique of forming the compressive stress field close to the outer peripheral region (edge members) on the main surface of the semiconductor device.

Patent Document 1 and Patent Document 2 are silent about “the technique of reducing the chipping and the microcrack on the sides of the semiconductor device, and reducing the sizes thereof if any” and “the technique of reducing the fracture of the semiconductor device by forming the compressive stress field close to the peripheral edge on the main surface of the semiconductor device”, the inventors of the present invention has developed them first time ever.

### SUMMARY OF THE INVENTION

Preferred embodiments of the present invention provides a semiconductor device which suppresses the chip fracture extending from the edge side even in a case where the semiconductor device has the chipping or the microcrack on the edge side thereof.

A semiconductor device according to an aspect of an example embodiment of the present invention includes a semiconductor layer made of a single crystal, the semiconductor device comprises a mounted surface on which an element is mounted, a non-mounted surface opposed to the mounted surface, and a compressive stress field in an outer peripheral region on at least one of the mounted surface and the non-mounted surface.

The compressive stress field can be measured by a microscopic Raman spectroscopy. A microscopic Raman spectrometer is commercially available for measurement of the compressive stress field by the microscopic Raman spectroscopy.

The semiconductor device may further comprise a conductive layer on the non-mounted surface, and the semiconductor device is brought into an operable state by applying a voltage between the mounted surface and the non-mounted surface.

The single crystal may be a SiC single crystal.

The compressive stress field may be located in a range of 5 μm or less from the mounted surface or the non-mounted surface along a thickness direction of the semiconductor layer and is located in a range of 50 μm or less from a side surface toward a center of the semiconductor layer.

The compressive stress field may include a first compressive stress field and a second compressive stress field which are sequentially located in a direction from the side toward the center, and the second compressive stress field has a second compressive stress distribution converging to zero toward the center of the semiconductor layer.

The first compressive stress field may consist solely of compressive stress, and the second compressive stress field has a stress distribution different from ones of the first compressive stress field and a tensile stress field between the first compressive stress field and the second compressive stress field.

A maximum value of the compressive stress in the first compressive stress field may be in a range of more than 0 MPa and not more than 200 MPa.

The semiconductor device may be produced by forming a scribe line on the semiconductor wafer with use of a scribing wheel and then applying an external force along the scribe line to divide the semiconductor wafer.

The semiconductor device may further comprise a side surface of the semiconductor layer including a vertical crack surface formed by a vertical crack generated when the scribe line is formed and a divided surface formed when the semiconductor wafer is divided by applying the external force along the scribe line.

The side surface of the semiconductor layer may include the vertical crack surface adjacent to the mounted surface and the divided surface adjacent to the non-mounted surface, or may include the divided surface adjacent to the mounted surface and the vertical crack surface adjacent to the non-mounted surface.

The compressive stress field may be located within the vertical crack surface.

The vertical crack surface may have a thickness along a thickness direction of the semiconductor layer which is equal to or smaller than 20% of an overall thickness of the semiconductor layer.

The above and other elements, features, steps, characteristics and advantages of the present invention will become more apparent from the following detailed description of the example embodiments with reference to the attached drawings.

### BRIEF DESCRIPTION OF THE DRAWINGS

A more complete appreciation of example embodiments of the present invention and many of the attendant advantages thereof will be readily obtained as the same becomes better understood by reference to the following detailed description when considered in connection with the accompanying drawings described below.

FIG. 1A is a schematic plan view of a conventional semiconductor device having a tensile stress field in an outer peripheral region.

FIG. 1B is a schematic plan view of a semiconductor device according to the preferred embodiment of the present invention, having a compressive stress field in an outer peripheral region of a semiconductor device.

FIG. 2A are photographs showing top and bottom surfaces and enlarged portions of conventional semiconductor devices and enlarged portions thereof, which include chipping on the edge sides thereof.

FIG. 2B are photographs showing top and bottom surfaces and enlarged portions of semiconductor devices according to the preferred embodiment, which include no chipping on the edge sides thereof.

FIG. 3 is a graph of stress in cross sections extending parallel to OF at positions away from side surface to illustrate stress distributions close to edge sides of the SiC semiconductor devices of the embodiment and the comparative example.

FIG. 4 is a graph illustrating and comparing bending strengths of the SiC semiconductor device produced by the SnB (Scribe and Break) process of the preferred embodiment and by the Blade Dicing process the Laser modification process of the comparative examples.

FIG. 5 is a schematic perspective view of the SiC semiconductor wafer from which a plurality of the SiC semiconductor devices are produced.

FIG. 6A is schematic cross-sectional view of the SiC semiconductor device of the preferred embodiment.

FIG. 6B is schematic perspective view of the SiC semiconductor device of the preferred embodiment.

### DETAILED DESCRIPTION OF THE EXAMPLE EMBODIMENTS

The example embodiments will now be described with reference to the accompanying drawings, wherein like reference numerals designate corresponding or identical elements throughout the various drawings. The drawings are to be viewed in an orientation in which the reference numerals are viewed correctly.

Example embodiments of the present invention will be described below with reference to the drawings.

A preferred embodiment of a SiC (silicon carbide) semiconductor device (hereinafter referred to as a “chip”) of the present invention will be described with reference to the drawings. This embodiment is a specific example of the present invention and the present invention is not limited thereto. In the drawings, SnB stands for a “Scribing and Breaking” process of the embodiment, and other types of dividing processes (e.g., dicing and laser) are referred to as conventional processes.

In the present embodiment, a semiconductor layer is composed of a single crystal which is a hexagonal SiC single crystal, specifically, a 4H(Hexagonal)-SiC single crystal. The present invention is also applicable to a hexagonal SiC single crystal such as a 2H—SiC single crystal or a 6H—SiC single crystal as the single crystal composing the semiconductor layer. The chip of the present invention can be used as a power device, a high-frequency device, a compound semiconductor, or the like.

A SiC semiconductor wafer (hereinafter referred to as a “wafer”) is described.

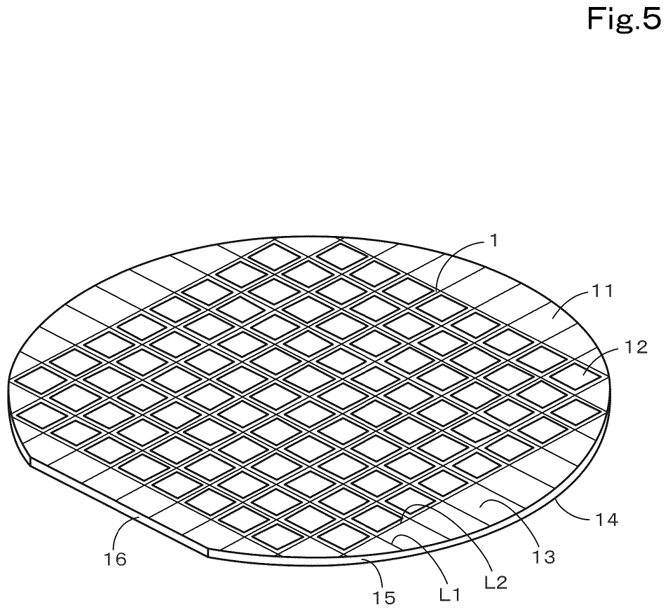

FIG. 5 illustrates a wafer 11. The wafer 11 is a substrate of brittle material and is a base material of the chips 1.

The wafer 11 is shaped in a disk and has a first wafer main surface 13 on a first side, a second wafer main surface 14 on a second side, and a wafer peripheral side 15 that connects the first wafer main surface 13 to the second wafer main surface 14. The wafer 11 includes a plurality of element-formed regions 12 each having an element formed thereon and corresponding to a chip 1 formed on the first wafer main surface 13. The wafer 11 includes a cut-out portion formed on the wafer peripheral side 15. The cut-out portion is referred to as an orientation flat (OF), which is a mark indicating the crystal orientation of the SiC single crystal. For example, one or two of orientation flats may be provided. A plurality of chips 1 are diced by dividing the wafer 11.

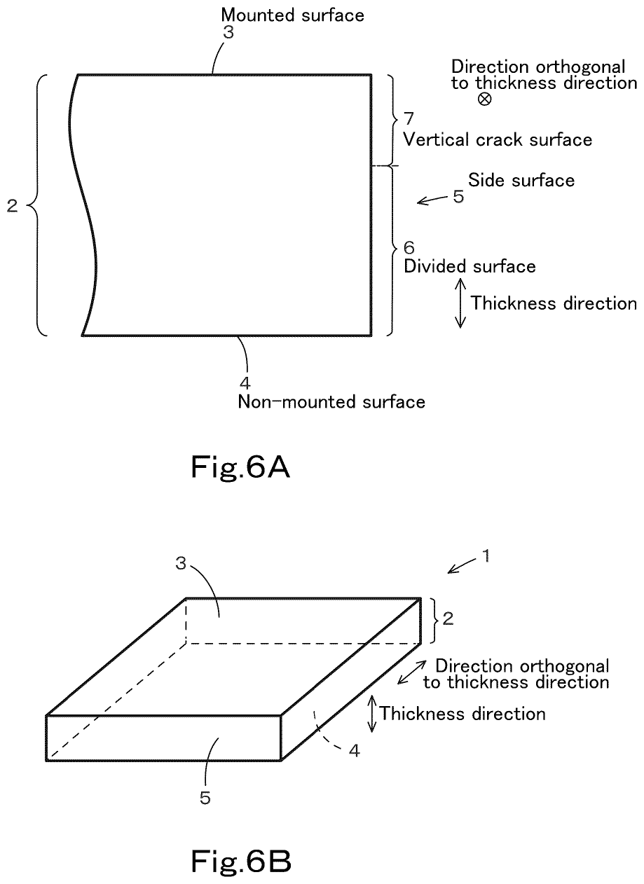

As illustrated in FIG. 6, the chip 1 of the present preferred embodiment of the present invention includes a semiconductor layer 2 which is composed of a 4H—SiC single crystal. The semiconductor layer 2 is diced and shaped into a plurality of chips 1. The semiconductor layer 2 has a first main surface 3 (top surface) on one hand, a second main surface 4 (bottom surface) on the other hand, and a side surface 5 that connects the first main surface 3 and the second main surface 4.

The first main surface 3 and the second main surface 4 have an identical quadrangular shape (a square shape in the present preferred embodiment) in a plan view. The first main surface 3 faces the (0001) plane (silicon surface) of the SiC single crystal, and the second main surface 4 faces the (000-1) plane (carbon surface). The (0001) plane and the (000-1) plane correspond to a {0001} plane.

In FIG. 6, the up-down direction is a thickness direction of the semiconductor layer 2, and the depth direction (front-back direction) and the width direction (left-right direction) are directions orthogonal to the thickness direction of the semiconductor layer 2.

The first main surface 3 is a mounted surface (element-formed surface) on which an element is mounted. The second main surface 4 is a non-mounted surface which is fixed to a supporting member. In a case where the chip 1 is mounted on the supporting member, the semiconductor layer 2 is mounted on the supporting member in such a posture that the second main surface 4 faces the supporting member.

Each of the chips 1 having the semiconductor layer 2 includes four side surfaces 5, each of which is on a crystal plane (cleavage plane) of the SiC single crystal.

A process for producing the chips 1 each having residual stress field will be described herein. A plurality of the chips 1 can be, for example, produced by forming a plurality of scribe lines L1 (L2) on the wafer 11 with use of a scribing tool (e.g., a scribing wheel) and then applying external force along the scribe lines L1 (L2) to break or divide the wafer 11 (scribing and breaking (SnB) process). The scribing wheel is pressed onto the wafer 11 to form the scribe lines L1 (L2) so that a compressive stress field 8 is formed in an outer peripheral region on either one of the mounted surface 3 or the non-mounted surface 4 of the chip 1 on which the scribe line L1 (L2) is formed. The outer peripheral region is located close to edge members on the mounted surface 3 or the non-mounted surface 4 of the chip 1 along which the scribe line L1 (L2) is formed for production thereof. That is, compressive stress remains in the compressive stress field 8 associated with and along a trace of the scribe line L1 (L2). Note that the side surface 5 is on the cleavage plane of the SiC single crystal, having little chipping and few microcracking thereon.

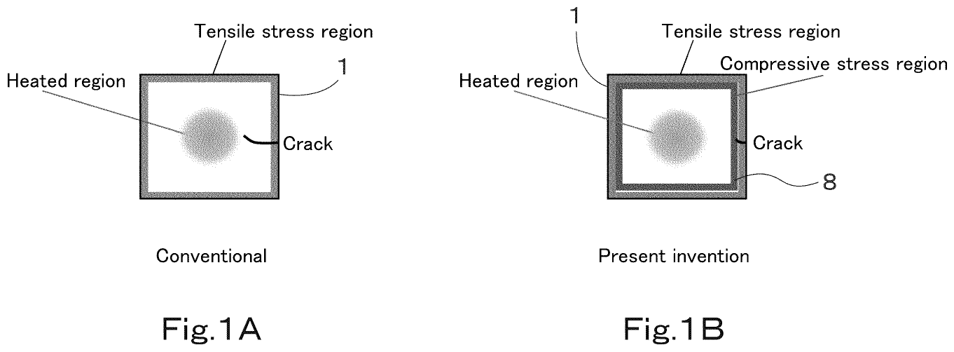

In recent years, most of semiconductor devices have achieved higher performance and integration, which exhibit tendency toward a larger amount of heat generation during operation. As illustrated in FIG. 1A, in a case where a semiconductor device generates heat, tensile stress acts on the chip 1, and the chip 1 may be fractured starting from chipping or microcracking on the edge side of the chip 1. This affects device functions or breaks the semiconductor device itself.

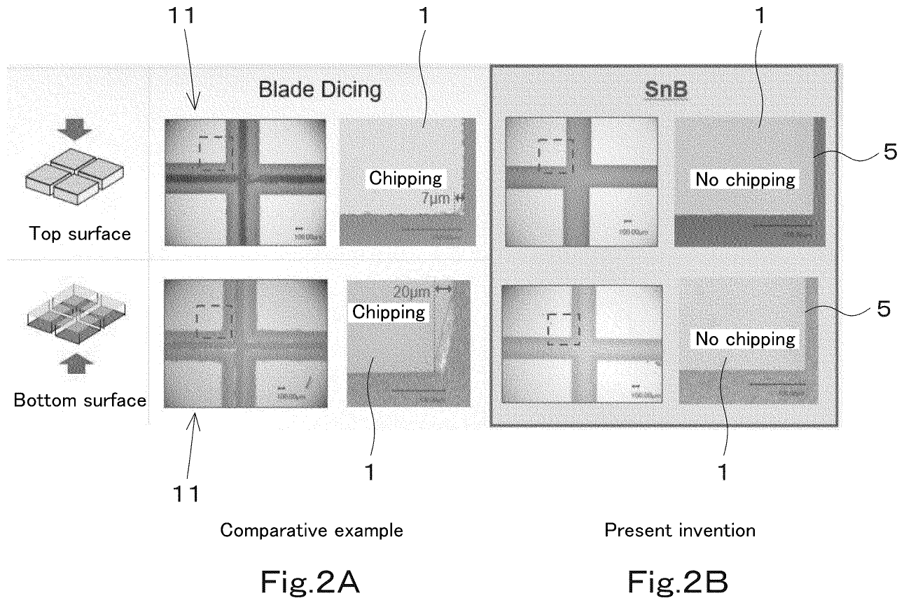

As illustrated in FIG. 1B and FIG. 2, the chip 1 of the present preferred embodiment is individualized by the scribing and breaking process, to cause little chipping and few microcracking on the edge side, which in turn reduces the chip in size, and further provides the compressive stress field 8 close to the edge members of the chip 1. The compressive stress field 8 reduces occurrence of a fracture extending from the edge side of the chip 1 and improves the bending strength and reliability.

The conventional blade dicing process scrapes or digs the wafer 11, which likely causes chipping and microcracking at the edge members (edges) of the chips 1 (see the left diagram of FIG. 2). Contrary, since the scribing and breaking process of the present preferred embodiment does not scrape or dig the wafer 11, chipping and microcracking at the edge members of the obtained chips 1 are less likely caused (see the right diagram of FIG. 2).

The chip 1 of the present preferred embodiment has a conductive layer on the non-mounted surface 4. While the chip 1 is intended as an FET element that is operable by applying a voltage between the mounted surface 3 and the non-mounted surface 4, the present invention is not limited to the FET element.

In the present embodiment, the compressive stress field 8 formed close to the edge members of the chip 1 is desirably located, along a thickness direction, in a range of 10 μm or less, especially in a range of 5 μm or less of the semiconductor layer from the mounted surface 3 or the non-mounted surface 4, and is desirably located, along a direction orthogonal to the thickness direction, in a range of 50 μm or less, especially in a range of 10 μm or less from the side surface 5 toward a center of the semiconductor layer.

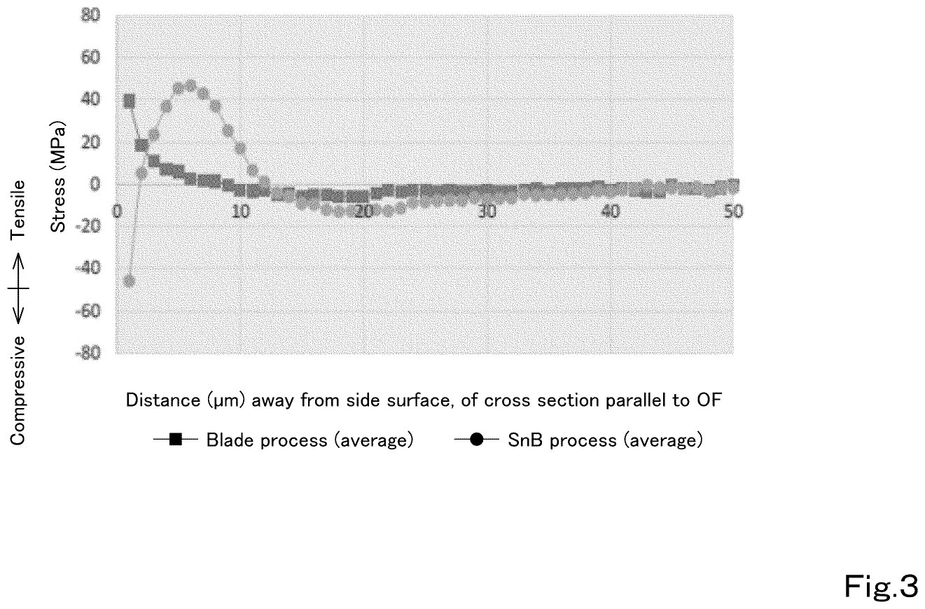

In particular, it is desirable that the compressive stress field includes a first compressive stress field and a second compressive stress field sequentially located from the side surface of the chip 1 toward the center, a tensile stress field is located between the first compressive stress field and the second compressive stress field, and a compressive stress distribution in the second compressive stress field converges to zero toward the center, as illustrated in FIG. 3. The first compressive stress field may consist solely of compressive stress, and the second compressive stress field may have a stress distribution different from ones of the first compressive stress field and the tensile stress field. Note that FIG. 3 illustrates residual stress measured at a depth of 1 μm from the uppermost face at each point in a range of 0 μm to 50 μm from the end surface of the chip 1. A maximum value of the compressive stress in the first compressive stress field is preferably in a range of more than 0 MPa and not more than 200 MPa, more preferably in a range of not less than 10 MPa and not more than 100 MPa, further more preferably in a range of not less than 20 MPa and not more than 80 MPa.

The wafer 11 of crystalline brittle material is scribed and divided (broken) to produce the chip 1 whose side surface is on a cleavage plane (a crystal plane of the SiC single crystal), which has a compressive stress field in the outer peripheral region (close to the edge members) of the top surface or the bottom surface of the chip 1.

The breaking after the scribing allows an appropriate compressive stress field 8 to remain close to the edge members of the chip 1 by selection (optimization) of a scribing condition and a breaking condition (especially the scribing condition).

Examples of selection conditions of scribing and breaking for allowing an appropriate compressive stress field 8 to remain close to the edge members of the chip 1 include specifications of the scribing tool (e.g., an external diameter of the scribing wheel, a cutting edge angle, and cutting edge microfabrication), a scribing load, a scanning speed of the scribing wheel, specifications of the breaking bar (e.g., a cutting edge angle and a tip shape of the cutting edge), a receiving blade interval, a table hardness, a breaking load (pushing amount), and a speed of pushing down the breaking bar, and the cutting edge angle of the scribing wheel and the scribing load are important selection conditions. For example, a formation state (a manner of convergence) and a formation position (e.g., a position in the thickness direction of the semiconductor layer and a position in a direction from the side surface toward the central portion) of a compressive stress field can be adjusted by selection of the cutting edge angle of the scribing wheel, cutting edge microfabrication (e.g., groove formation), and the scribing load.

A scribing device for forming the scribe line L1 (L2) on the wafer 11 and a breaking device for dividing the wafer 11 along the scribe line L1 (L2) to produce the chip 1, as one example of the devices performing the scribing and breaking process. The scribing device and the breaking device may integrally be combined.

The scribing apparatus includes a table on which the wafer 11 is seated, a scribing head for forming a plurality of scribe lines L (L2) (vertical cracks) on the main surface of the wafer 11, and a scribing beam on which the scribing head are disposed. Note that the scribe line L1 (L2) may be formed in an X-axis direction (a width direction: a longitudinal direction of the scribe beam) of the wafer 11 and a Y-axis direction (a feeding direction: a movement direction of the table) orthogonal to the X-axis direction.

The scribing apparatus includes a first scribe head and a second scribe head. For example, the first scribe head is movable in the X-axis direction (the width direction of the wafer 11) along a guidance of the scribing beam having a gate-shaped intensity or a flat-top profile distribution intensity by driving of a motor.

The first scribe head is provided with a first scribing tool that forms the scribe line L1 on the wafer 11 in the X-axis direction. The second scribe head is provided with a second scribing tool that forms the scribe line L2 on the wafer 11 in the Y-axis direction. The first scribing tool forms the scribe line in the X-axis direction as the first scribe head moves in the X-axis direction. The second scribing tool forms the scribe line in the Y-axis direction as the table on which the wafer 11 is placed moves in the Y-axis direction. Each of the scribe heads is movable in the Z-axis direction.

The breaking apparatus divides the wafer 11 into a plurality of substrates (chips 1) by pressing the breaking bar from above onto the wafer 11 having the scribe line L1 (L2) along the scribe line L1 (L2).

The breaking apparatus includes a breaking table for the wafer 11 to be seated and divided, a breaking unit suspended over the table, and a beam oscillator irradiating to the table, a guidance beam having a gate-shaped intensity or a flat-top profile distribution intensity. The breaking unit includes a first breaking bar for dividing the wafer 11 along the scribe line L1 in the X-axis direction and a second breaking bar for dividing the wafer 11 along the scribe line L2 in the Y-axis direction. Each of the first and second breaking bars has, at a tip (lower end), a blade (linear ridge) that divides the wafer 11 along the scribe line L1 or L2. Each of the first and second breaking bars is operable to move upward and downward in the Z-axis direction with respect to the beam by an elevating mechanism. Instead of the break table, a pair of two receiving blades that receive pressing force from the wafer 11 against which the breaking bar is pressed during breaking may be used.

The structures of the scribing apparatus and the breaking apparatus are not limited to those as described above. For example, in a case where the first scribe head of the scribing device is rotatable around the Z-axis direction, the scribe lines in the X-axis direction and the scribe line in the Y-axis direction can be formed only by the first scribe head (without the need for the second scribe head). Furthermore, in a case where the wafer 11 is rotatable about the Z-axis direction, the breaking device can divide the wafer 11 along the scribe line in the X-axis direction and divide the wafer 11 along the scribe line in the Y-axis direction only by the first breaking bar (without the need for the second breaking bar).

Referring to FIG. 6, a side surface 5 of the semiconductor layer 2 (the semiconductor chip 1) will be described in detail. As illustrated in FIG. 6, in the chip 1 obtained by breaking after scribing, the side surface 5 of the semiconductor layer 2 has a vertical crack surface 7 corresponding to a vertical crack generated when the scribe line L1 (L2) is formed and a divided surface 6 formed when the wafer 11 is divided by applying external force along the scribe line L1 (L2).

When the scribe line L1 (L2) is formed on the wafer 11 by the scribing tool, a crack extends straight in the depth direction, and thereby a vertical crack having a constant depth is formed. This vertical crack forms the “vertical crack surface 7” of the side surface 5 of the semiconductor layer 2 of the chip 1 obtained after the breaking.

When the breaking bar is pressed onto the wafer 11 during the breaking, the wafer 11 is cleaved starting from the vertical crack due to cleavability of the SiC single crystal, and thereby a smooth cleavage plane (a crystal plane of the SiC single crystal) is exposed. This cleavage plane forms the “divided surface 6” of the side surface 5 of the semiconductor layer 2 when the chip 1 is obtained after the breaking.

A portion of the side surface 5 adjacent to the mounted surface 3 may be the vertical crack surface 7 and a portion of the side surface 5 adjacent to the non-mounted surface 4 may be the divided surface 6. Alternatively, a portion of the side surface 5 adjacent to the mounted surface 3 may be the divided surface 6 and a portion of the side surface 5 adjacent to the non-mounted surface 4 may be the vertical crack surface 7. In either case, the compressive stress field is present within a region of the vertical crack surface 7.

A thickness (depth) of the vertical crack surface 7 along the thickness direction of the semiconductor layer 2 is equal to or smaller than 20% of the thickness of the semiconductor layer 2. When the depth of the vertical crack surface 7 exceeds a prescribed value, it is sometimes hard to obtain a desired cleavage plane.

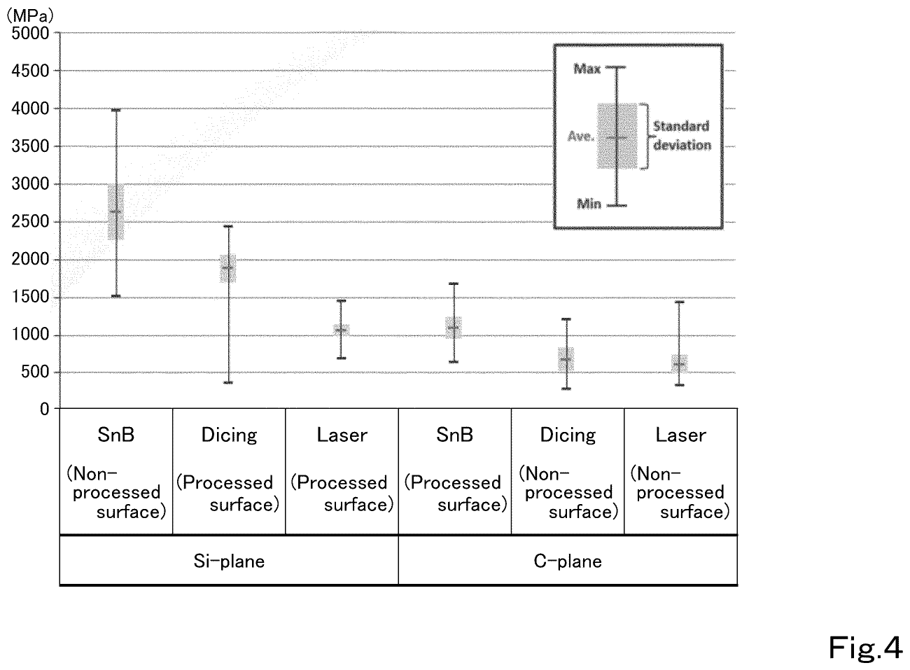

FIG. 4 compares bending strengths of the chips produced by the SnB (Scribe and Break) process of the preferred embodiment to ones produced by the Blade Dicing process the Laser modification process. The “Processed surface” of FIG. 4 means a surface corresponding to a surface on which a scribe line is formed in a case where the wafer is divided by breaking after scribing to obtain chips, a surface with which a dicing blade is brought into contact in the case of dicing, and a surface corresponding to a laser irradiation surface in the case of laser processing, and the “Non-Processed surface” of FIG. 4 means bottom surfaces opposite to the “Processed surface”.

As illustrated in FIG. 4, the chip 1 of the preferred embodiment has a higher bending strength due to the compressive stress field 8 close to the edge side than the chips obtained by the other processes.

In the chip 1 of the preferred embodiment, the compressive stress field 8 is located in the outer peripheral portion (close to the edge side) of at least one of the mounted surface 3 and the non-mounted surface 4, and therefore occurrence of a fracture extending from an end surface is reduced.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A semiconductor device including a semiconductor layer composed of a single crystal, comprising:
a mounted surface on which an element is mounted;
a non-mounted surface opposed to the mounted surface; and
a compressive stress field in an outer peripheral region on at least one of the mounted surface and the non-mounted surface.

2. The semiconductor device according to claim 1, further comprising:
a conductive layer on the non-mounted surface, wherein
the semiconductor device is brought into an operable state by applying a voltage between the mounted surface and the non-mounted surface.

3. The semiconductor device according to claim 1, wherein
the single crystal is a SiC single crystal.

4. The semiconductor device according to claim 1, wherein
the compressive stress field is located in a range of 5 μm or less from the mounted surface or the non-mounted surface along a thickness direction of the semiconductor layer and is located in a range of 50 μm or less from a side surface toward a center of the semiconductor layer.

5. The semiconductor device according to claim 4, wherein
the compressive stress field includes a first compressive stress field and a second compressive stress field which are sequentially located in a direction from the side toward the center, and
the second compressive stress field has a second compressive stress distribution converging to zero toward the center of the semiconductor layer.

6. The semiconductor device according to claim 5, wherein
the first compressive stress field consists solely of compressive stress, and
the second compressive stress field has a stress distribution different from ones of the first compressive stress field and a tensile stress field between the first compressive stress field and the second compressive stress field.

7. The semiconductor device according to claim 5, wherein
a maximum value of the compressive stress in the first compressive stress field is in a range of more than 0 MPa and not more than 200 MPa.

8. The semiconductor device according to claim 1, wherein
the semiconductor device is produced by forming a scribe line on the semiconductor wafer including a semiconductor layer composed of a single crystal with use of a scribing wheel and then applying an external force along the scribe line to divide the semiconductor wafer.

9. The semiconductor device according to claim 8, further comprising:
a side surface of the semiconductor layer including a vertical crack surface formed by a vertical crack generated when the scribe line is formed and a divided surface formed when the semiconductor wafer is divided by applying the external force along the scribe line.

10. The semiconductor device according to claim 9, wherein
the side surface of the semiconductor layer includes the vertical crack surface adjacent to the mounted surface and the divided surface adjacent to the non-mounted surface.

11. The semiconductor device according to claim 9, wherein
the side surface of the semiconductor layer includes the divided surface adjacent to the mounted surface and the vertical crack surface adjacent to the non-mounted surface.

12. The semiconductor device according to claim 9, wherein
the compressive stress field is located within the vertical crack surface.

13. The semiconductor device according to claim 9, wherein
the vertical crack surface has a thickness along a thickness direction of the semiconductor layer which is equal to or smaller than 20% of an overall thickness of the semiconductor layer.
